(19) United States
(12) Patent Application Publication
(10) Pub. No.: US 2026/0006852 A1
(43) Pub. Date: Jan. 1, 2026

(54) SEMICONDUCTOR DEVICE INCLUDING BACKSIDE CONTACT PLUG

(71) Applicant: SAMSUNG ELECTRONICS CO., LTD., Suwon-si (KR)

(72) Inventors: Seunggeun JUNG, Suwon-si (KR); Dongwon KIM, Suwon-si (KR); Changwoo NOH, Suwon-si (KR); Beomjin PARK, Suwon-si (KR)

(73) Assignee: SAMSUNG ELECTRONICS CO., LTD., Suwon-si (KR)

(21) Appl. No.: 19/028,030

(22) Filed: Jan. 17, 2025

(30) Foreign Application Priority Data
Jun. 28, 2024 (KR) 10-2024-0085612

(51) Int. Cl. H10D 30/67; H01L 23/528; H10D 62/13; H10D 62/60

(52) U.S. Cl. CPC H10D 30/6757; H01L 23/5286; H10D 62/151; H10D 62/60; H10D 30/6735

(57) ABSTRACT

A semiconductor device includes: a first source/drain region and a second source/drain region on a first channel structure; a third source/drain region and a fourth source/drain region on a second channel structure; a first backside contact plug recessing the second source/drain region by a first depth from a lower surface of the second source/drain region; and a second backside contact plug recessing the fourth source/drain region by a second depth, smaller than the first depth, from a lower surface of the fourth source/drain region, wherein the second source/drain region comprises a first impurity region comprising a first impurity on an interface with the first backside contact plug, and the fourth source/drain region comprises another first impurity region comprising a second impurity on an interface with the second backside contact plug.

### CROSS-REFERENCE TO RELATED APPLICATION

This application is based on and claims benefit of priority to Korean Patent Application No. 10-2024-0085612 filed on Jun. 28, 2024 in the Korean Intellectual Property Office, the disclosure of which is incorporated herein in its entirety by reference.

### BACKGROUND

The present inventive concept relates to a semiconductor device based on a backside power delivery network (BSPDN) structure including a backside contact plug.

As the demand for high performance, high speed, multifunctionality, and the like of semiconductor devices increases, a degree of integration of semiconductor devices is increasing. In accordance with the trend toward a high degree of integration of semiconductor devices, semiconductor devices having the BSPDN structure in which power rails are disposed on a rear surface (back side) of a wafer are being developed. In addition, efforts are being made to develop semiconductor devices including a fin field-effect transistor (FinFET) having a three-dimensional channel structure in order to overcome limitations of operating characteristics due to a decrease in size of a planar metal-oxide semiconductor FET (MOSFET).

### SUMMARY

An aspect of the present inventive concept is to provide a semiconductor device having improved electrical characteristics.

According to an aspect of the disclosure, there is provided a semiconductor device which may include: a first source/drain region and a second source/drain region on a first channel structure; a third source/drain region and a fourth source/drain region on a second channel structure; a first backside contact plug recessing the second source/drain region by a first depth from a lower surface of the second source/drain region; and a second backside contact plug recessing the fourth source/drain region by a second depth, smaller than the first depth, from a lower surface of the fourth source/drain region, wherein the second source/drain region comprises a first impurity region comprising a first impurity on an interface with the first backside contact plug, and the fourth source/drain region comprises another first impurity region comprising a second impurity on an interface with the second backside contact plug.

According to an aspect of the disclosure, there is provided a semiconductor device which may include: a first source/drain region and a second source/drain region spaced apart from each other; and a first backside contact plug and a second backside contact plug on the first source/drain region and the second source/drain regions, respectively, wherein the first source/drain region includes a first impurity region along an interface with the first backside contact plug, and a second impurity region along a lower portion of the first source/drain region, wherein the second source/drain region includes a third impurity region along an interface with the second backside contact plug, and a fourth impurity region along a lower portion of the second source/drain region, and wherein the first impurity region includes an impurity different from an impurity in the third impurity region, and the second impurity region includes an impurity different from an impurity in the fourth impurity region.

According to an aspect of the disclosure, there is provided a semiconductor device which may include: a first source/drain region and a second source/drain region spaced apart from each other; a first backside contact plug recessing the first source/drain region by a first depth from a lower surface of the first source/drain region; and a second backside contact plug recessing the second source/drain region from a lower surface of the second source/drain region by a second depth, different from the first depth, wherein the first source/drain region includes a first impurity region including a first impurity in a region contacting the first backside contact plug, and the second source/drain region includes a second impurity region including a second impurity in a region contacting the second backside contact plug.

### BRIEF DESCRIPTION OF DRAWINGS

The above and other aspects, features, and advantages of the disclosure will be more clearly understood from the following detailed description, taken in conjunction with the accompanying drawings, in which:

FIG. 1 is a plan view illustrating a semiconductor device, according to one or more embodiments.

FIGS. 2A and 2B are cross-sectional views illustrating a semiconductor device, according to one or more embodiments.

FIG. 3 is a partial enlarged view illustrating a semiconductor device, according to one or more embodiments.

FIGS. 4A and 4B are partial enlarged views illustrating a semiconductor device, according to one or more embodiments.

FIGS. 5A and 5B are cross-sectional views illustrating a semiconductor device, according to one or more embodiments.

FIGS. 6A and 6B are cross-sectional views illustrating a semiconductor device, according to one or more embodiments.

FIGS. 7A and 7B are cross-sectional views illustrating a semiconductor device, according to one or more embodiments.

FIG. 8 is a cross-sectional view illustrating a semiconductor device, according to one or more embodiments.

FIGS. 9A to 9N are views illustrating a process sequence illustrating a method of manufacturing a semiconductor device, according to one or more embodiments.

### DETAILED DESCRIPTION

Hereinafter, embodiments of the disclosure will be described with reference to the accompanying drawings. All of these embodiments are non-limiting example embodiments, non-limiting example embodiments, and thus, the disclosure is not limited thereto and may be realized in various other forms. Hereinafter, it is to be understood that terms such as ‘on,’ ‘upper,’ ‘upper portion,’ ‘upper surface,’ ‘below,’ ‘lower,’ ‘lower portion,’ ‘lower surface,’ ‘side surface,’ and the like may be denoted by reference numerals and refer to the drawings, except where otherwise indicated. It is also to be understood that, although the terms first, second, third, fourth, etc. may be used herein to describe various elements, components, regions, layers and/or sections (collectively “elements”), these elements should not be limited by these terms. These terms are only used to distinguish one element from another element.

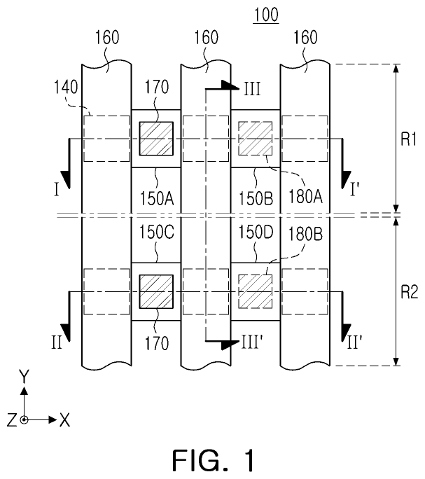

FIG. 1 is a plan view illustrating a semiconductor device according to example embodiments. For convenience of explanation, only some components of the semiconductor device are illustrated in FIG. 1.

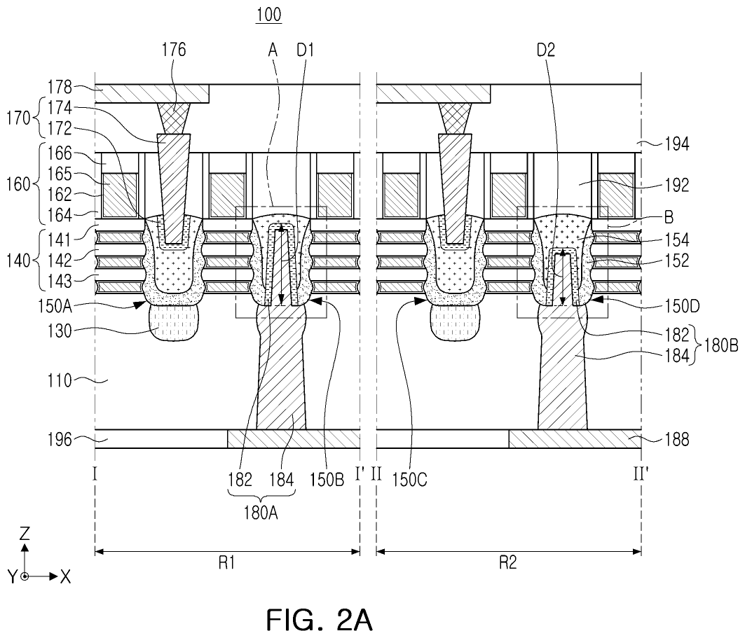

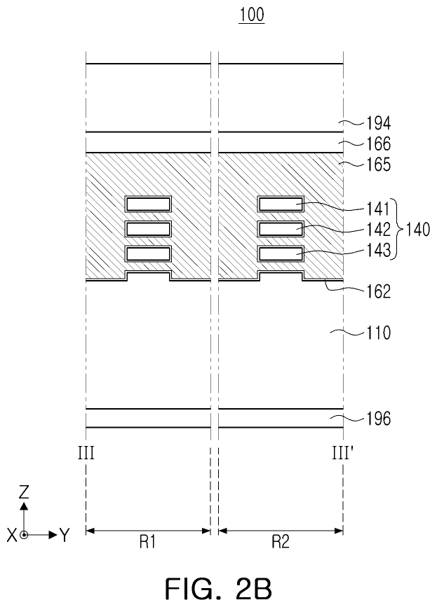

FIGS. 2A and 2B are cross-sectional views illustrating a semiconductor device, according to one or more embodiments. FIG. 2A illustrates a cross-section of the semiconductor device of FIG. 1, taken along lines I-I′ and II-II′, and FIG. 2B illustrates a cross-section of the semiconductor device of FIG. 1, taken along line III-III′.

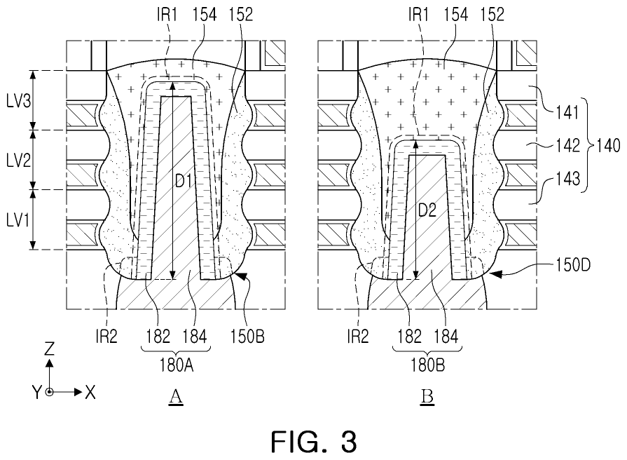

FIG. 3 is a partial enlarged view illustrating a semiconductor device, according to one or more embodiments. FIG. 3 illustrates an enlarged view of portions ‘A’ and ‘B’ in FIG. 2A.

Referring to FIGS. 1 to 3, a semiconductor device 100 may include a substrate insulating layer 110 having first and second regions R1 and R2, gate structures 160 extending on the substrate insulating layer 110 in one direction, each including a gate electrode 165, channel structures 140 including first to third channel layers 141, 142, and 143 arranged vertically and spaced apart from each other on the substrate insulating layer 110, first to fourth source/drain regions 150A, 150B, 150C, and 150D contacting the channel structures 140, front contact plugs 170 penetrating first and second interlayer insulating layers 192 and 194 and connected to the first and third source/drain regions 150A and 150C, first and second backside contact plugs 180A and 180B penetrating the substrate insulating layer 110 to be connected to the second and fourth source/drain regions 150B and 150D, respectively, upper interconnection lines 178 connected to the front contact plugs 170, and backside power structures 188 connected to the first and second backside contact plugs 180A and 180B. The semiconductor device 100 may further include placeholder layers 130 below the first and second source/drain regions 150A and 150B, upper contacts 176 on the front contact plugs 170, and first to third interlayer insulating layers 192, 194, and 196.

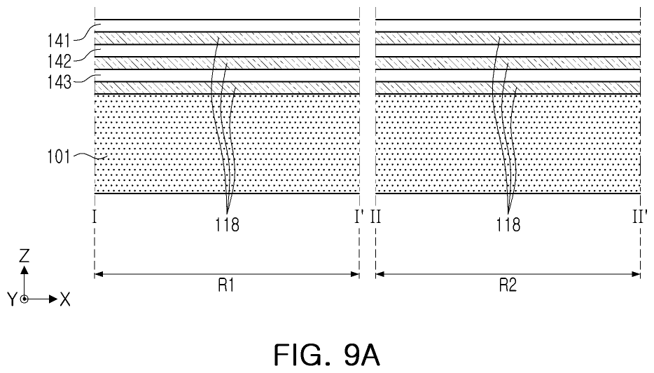

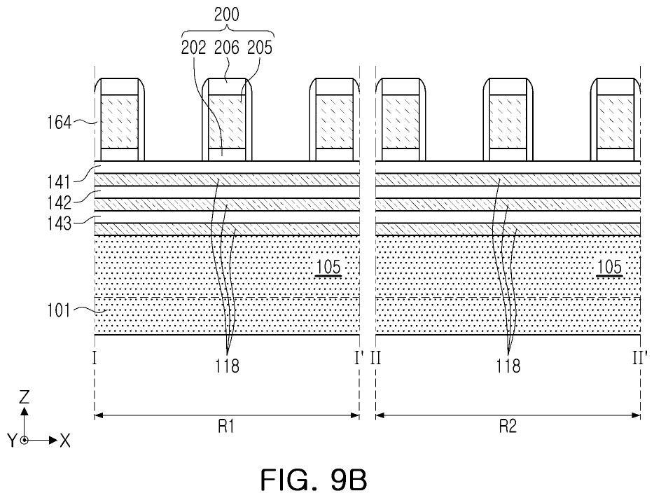

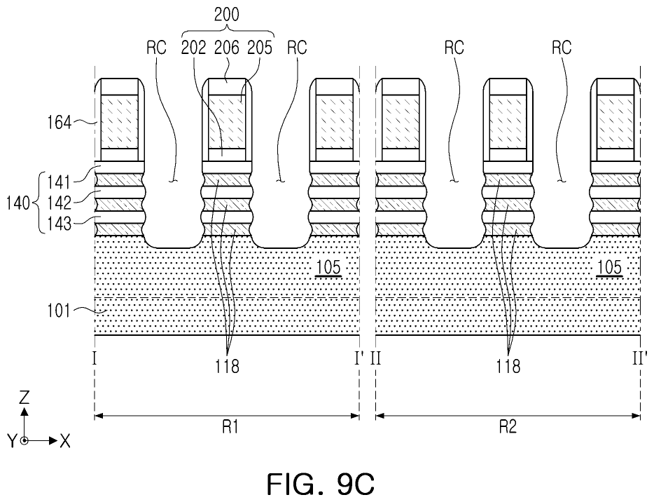

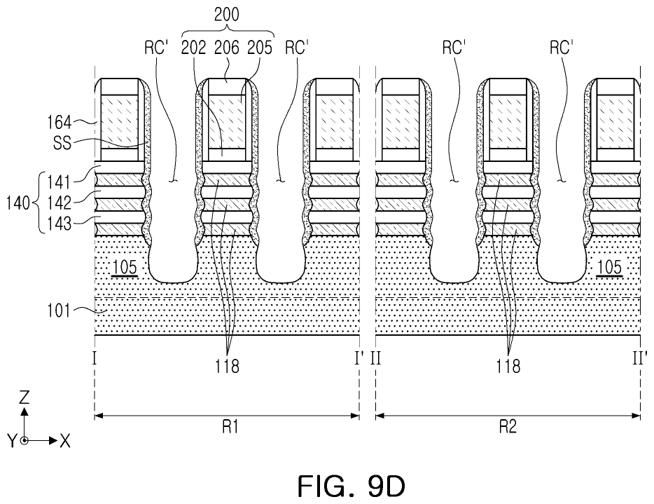

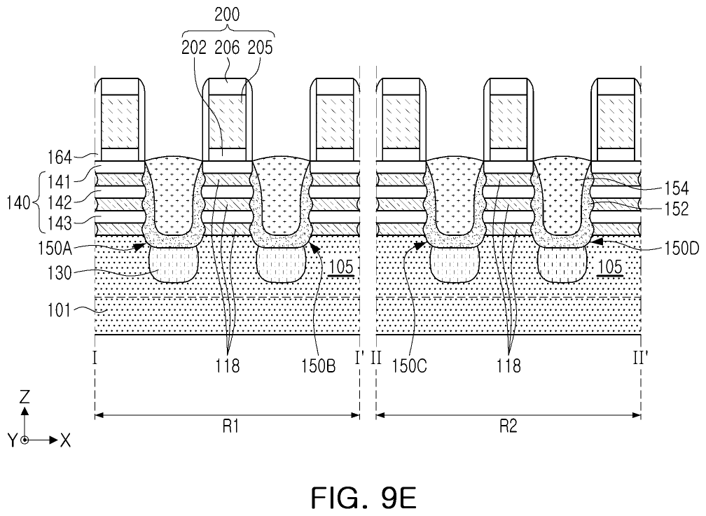

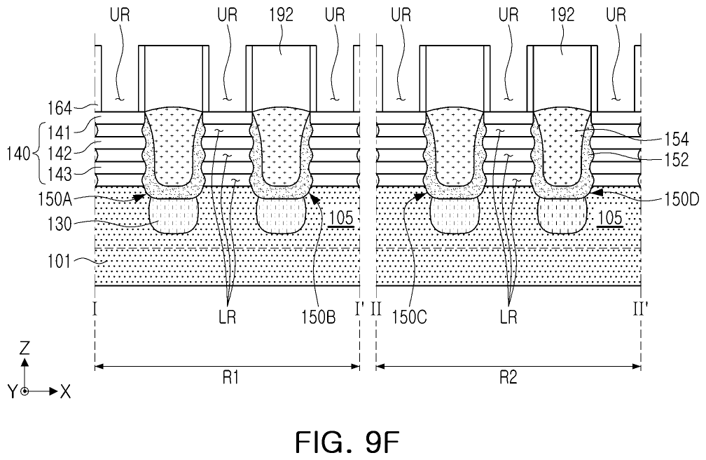

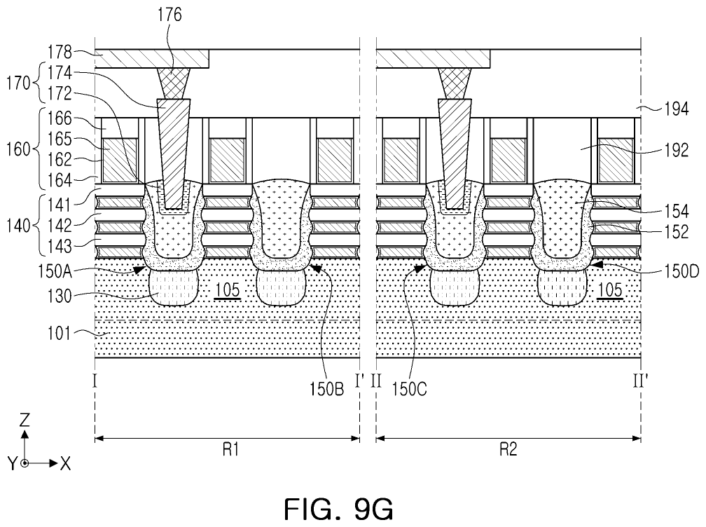

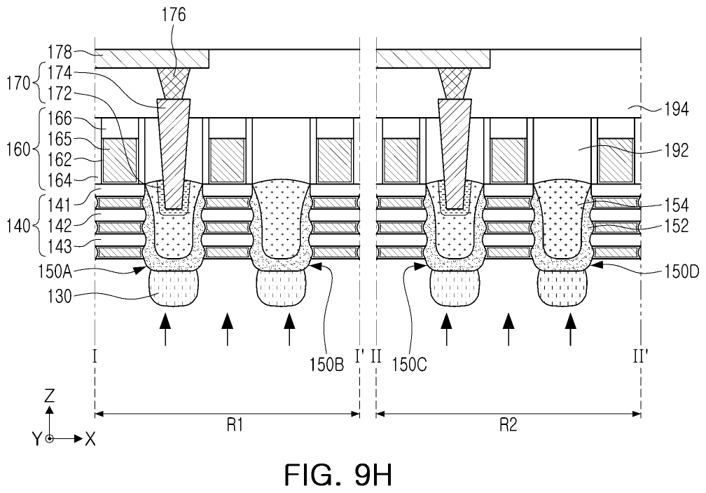

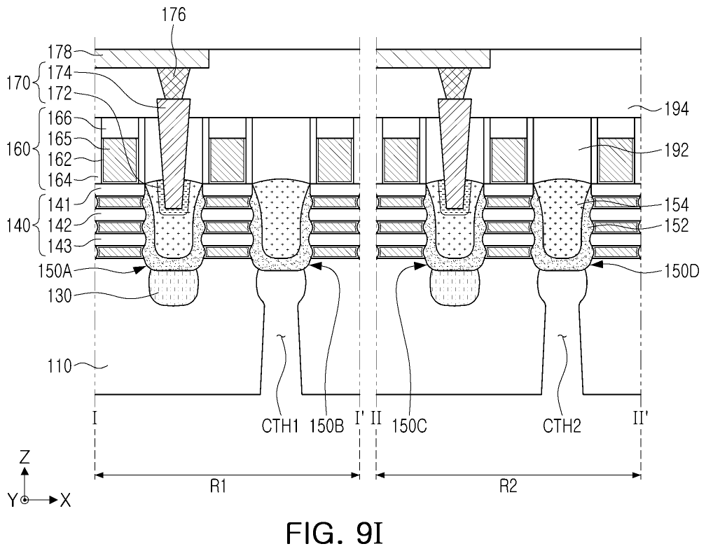

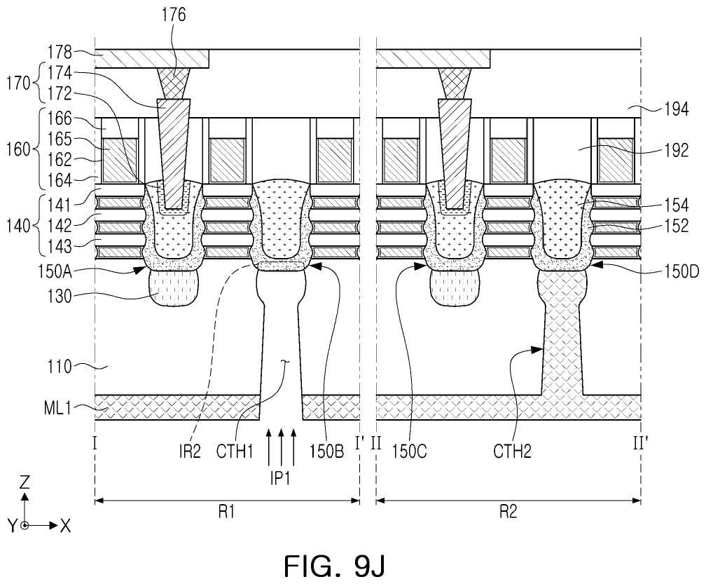

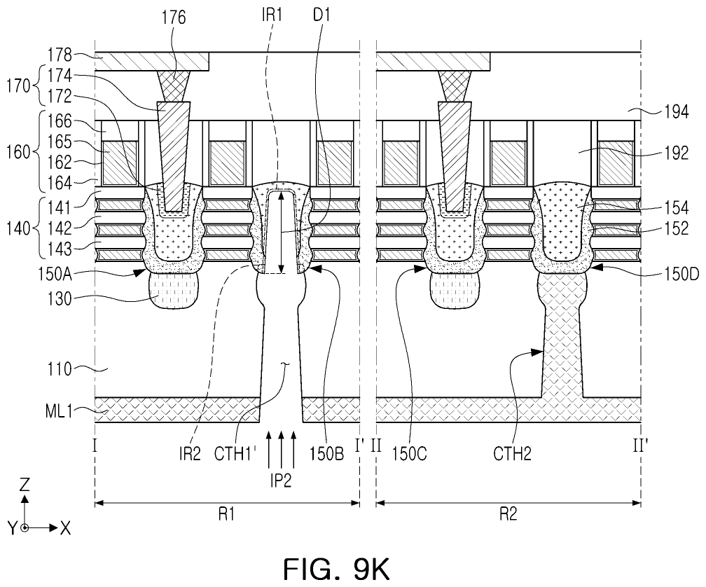

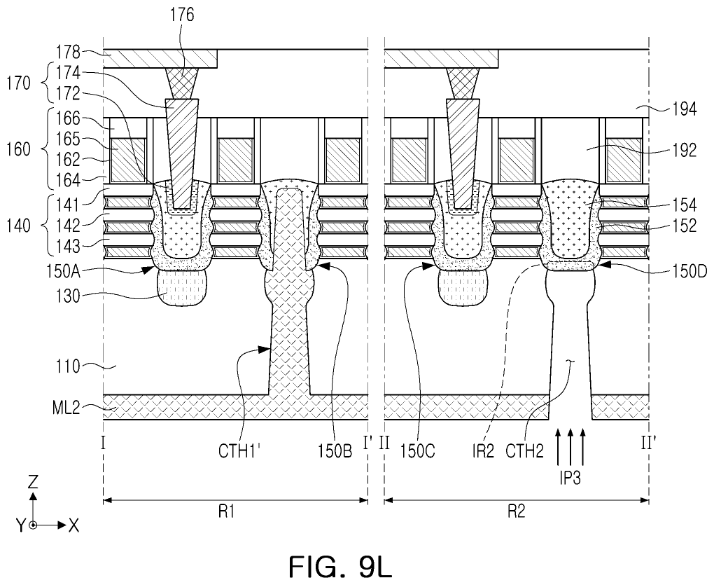

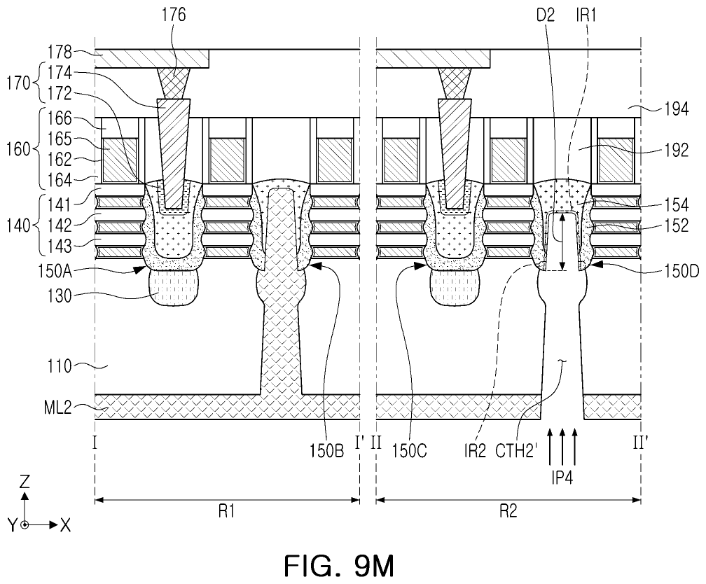

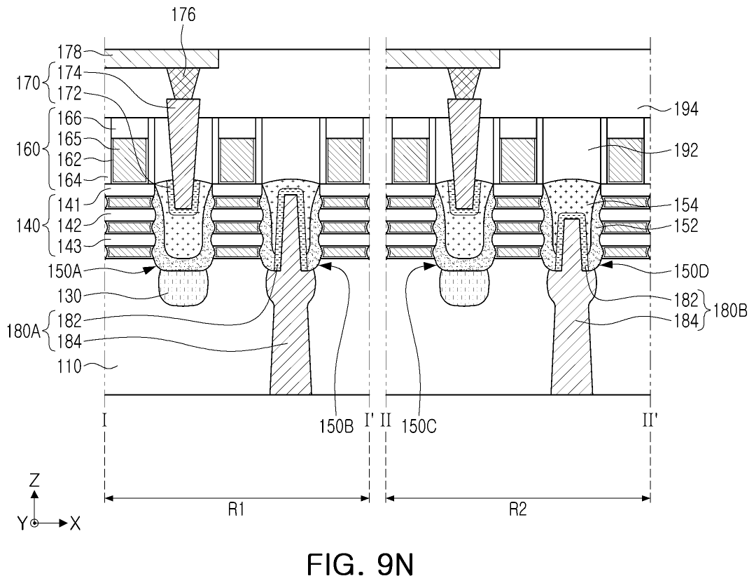

The substrate insulating layer 110 may have an upper surface extending in an X direction and a Y direction. The substrate insulating layer 110 may be a layer formed by removing and/or oxidizing a substrate 101 (see FIG. 9A) formed of a semiconductor material during a manufacturing process. The substrate insulating layer 110 may be formed of an insulating material, and may include, for example, an oxide, a nitride, or a combination thereof. According to one or more embodiments, the substrate insulating layer 110 may include a plurality of insulating layers.

The substrate insulating layer 110 may include the first and second regions R1 and R2, and the first and second regions R1 and R2 may be adjacent to or spaced apart from each other. In the first region R1, the first and second source/drain regions 150A and 150B and the first backside contact plug 180A may be disposed, and in the second region R2, the third and fourth source/drain regions 150C and 150D and the second backside contact plug 180B may be disposed. For example, the first region R1 may be an n-type field-effect transistor (nFET) region, and the second region R2 may be a p-type field-effect transistor (pFET) region. In one or more other embodiments, the first and second regions R1 and R2 may be regions in which transistors having the same conductivity type but different electrical characteristics are arranged. The first and second regions R1 and R2 may also be referred to as regions of the semiconductor device 100, not as regions of the substrate insulating layer 110.

The gate structures 160 may be disposed to extend in one direction, for example, in the Y direction, on the substrate insulating layer 110. Channel regions of the transistors may be formed in the channel structures 140 intersecting the gate electrode 165 of the gate structures 160. The gate structures 160 may be disposed to be spaced apart from each other in the X direction. Each of the gate structures 160 may include gate dielectric layers 162, gate spacer layers 164, a gate electrode 165, and a gate capping layer 166.

The gate dielectric layers 162 may be disposed between the substrate insulating layer 110 and the gate electrode 165 and between the channel structure 140 and the gate electrode 165, and may be disposed on at least a portion of surfaces of the gate electrode 165. For example, the gate dielectric layers 162 may be disposed to surround all surfaces except for the uppermost surface of the gate electrode 165. The gate dielectric layers 162 may extend between the gate electrode 165 and the gate spacer layers 164, but the disclosure is not limited thereto. The gate dielectric layers 162 may include an oxide, a nitride, or a high-k material. The high-K material may mean a dielectric material having a higher dielectric constant than a silicon dioxide (e.g., SiO₂). The high-K material may be, for example, any one of aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓOₓ), or praseodymium oxide (Pr₂O₃). According to one or more embodiments, the gate dielectric layer 162 may be formed in a multilayer structure.

The gate electrode 165 may include a conductive material, and may include, for example, a metal nitride such as titanium nitride (TiN), tantalum nitride (TaN), or in tungsten nitride (WN), and/or a metal material such as aluminum (Al), tungsten (W), or molybdenum (Mo), or a semiconductor material such as doped polysilicon. According to one or more embodiments, the gate electrode 165 may be formed in a multilayer structure. In a region not illustrated, the gate electrodes 165 may be connected to gate contact plugs disposed thereon.

The gate spacer layers 164 may be disposed on both side surfaces of the gate electrode 165 on the channel structure 140. The gate spacer layers 164 may insulate the source/drain regions 150 and the gate electrodes 165. According to one or more embodiments, a shape of an upper end of the gate spacer layers 164 may be variously changed, and the gate spacer layers 164 may be formed in a multilayer structure. The gate spacer layers 164 may include at least one of an oxide, a nitride, or an oxynitride, and may be formed as, for example, a low-K film.

The gate capping layer 166 may be disposed on the gate electrode 165, and may be disposed between the gate spacer layers 164. In one or more other embodiments, a lower surface of the gate capping layer 166 may have a convex shape in a downward direction. The gate capping layer 166 may include an insulating material, and may include at least one of an oxide, a nitride, or an oxynitride, for example.

The channel structures 140 may be disposed on the substrate insulating layer 110 to intersect the gate structures 160. Each of the channel structures 140 may include first to third channel layers 141, 142, and 143, which may be a plurality of, e.g., two or more channel layers spaced apart from each other in a Z direction. The first to third channel layers 141, 142, and 143 may be sequentially arranged from an upper portion of the channel structure 140. The channel structures 140 may be connected to the source/drain regions 150. The channel structures 140 may have a width, equal to or similar to a width of each of the gate structures 160 in the X direction. In a cross-section in the Y direction, among the first to third channel layers 141, 142, and 143, a channel layer arranged in a lower portion may have a width, equal to or greater than a width of a channel layer arranged in an upper portion. In one or more other embodiments, the channel structures 140 may have a reduced width compared to the gate structures 160, such that side surfaces in the X direction are disposed below the gate structures 160.

The channel structures 140 may be formed of a semiconductor material, and may include, for example, at least one of silicon (Si), silicon germanium (SiGe), or germanium (Ge). The number and shapes of the channel layers forming one channel structure 140 may be changed by embodiments.

In the semiconductor device 100, the gate electrode 165 may be disposed between the first to third channel layers 141, 142, and 143 of the channel structures 140 and on the channel structures 140. Therefore, the semiconductor device 100 may include a transistor having a multi bridge channel FET (MBCFET™) structure, which may be a gate-all-around type field effect transistor.

The first to fourth source/drain regions 150A, 150B, 150C, and 150D may be disposed on both sides of the gate structures 160 to contact the channel structures 140, respectively. The first to fourth source/drain regions 150A, 150B, 150C, and 150D may be disposed on side surfaces of the first to third channel layers 141, 142, and 143 of the channel structure 140 in the X direction, respectively. The first and third source/drain regions 150A and 150C may be respectively connected to the front contact plugs 170 through an upper surface or an upper end, and the second and fourth source/drain regions 150B and 150D may respectively be connected to the first and second backside contact plugs 180A and 180B through a lower surface or a lower end. The first to fourth source/drain regions 150A, 150B, 150C, and 150D may have a recessed shape by the front contact plugs 170 and the first and second backside contact plugs 180A and 180B. Upper (or top) surfaces of the first to fourth source/drain regions 150A, 150B, 150C, and 150D may be disposed at a level, the same as or higher than a level of a lower (or bottom) surface of the gate electrode 165 on the channel structure 140, and the levels may be variously changed in embodiments.

Each of the first to fourth source/drain regions 150A, 150B, 150C, and 150D may include first and second epitaxial layers 152 and 154. The first epitaxial layer 152 may be disposed on side surfaces of each of the first to third channel layers 141, 142, and 143 in the X direction, and may also be disposed on side surfaces of the gate structures 160 in the X direction below the channel structure 140. The first epitaxial layers 152 may extend to be disposed an inner side wall and a bottom surface of a recessed region in which each of the first to fourth source/drain regions 150A, 150B, 150C, and 150D is disposed. The first epitaxial layer 152 may have an outer side surface protruding convexly toward the gate structure 160 below the first to third channel layers 141, 142, and 143, and thus may have a curve on the outer side surface. A shape of the outer side surface of the first epitaxial layer 152 is not limited to those illustrated in FIG. 2A. In the second and fourth source/drain regions 150B and 150D, the first epitaxial layer 152 may be penetrated by the first and second backside contact plugs 180A and 180B, and may be in contact with the first and second backside contact plugs 180A and 180B.

The second epitaxial layer 154 may be disposed on the first epitaxial layer 152, and may fill the recess region. In the second and fourth source/drain regions 150B and 150D, the second epitaxial layer 154 may be in contact with at least upper ends of the first and second backside contact plugs 180A and 180B. A width of the second epitaxial layer 154 in the X direction may be greater than a width of the first epitaxial layer 152 in the X direction on one side surface of the channel structure 140. In one or more other embodiments, at least one of the first to fourth source/drain regions 150A, 150B, 150C, and 150D may further include a third epitaxial layer on an upper surface of the second epitaxial layer 154.

The first to fourth source/drain regions 150A, 150B, 150C, and 150D may include a semiconductor material, for example, at least one of silicon (Si) or germanium (Ge), and may further include impurities. The first and second epitaxial layers 152 and 154 may have different compositions. A concentration of a non-silicon element of the second epitaxial layer 154 may be higher than a concentration of a non-silicon element of the first epitaxial layer 152. The non-silicon element may be, for example, germanium (Ge) and/or a doping element.

For example, when the first region R1 is an nFET region and the second region R2 is e a pFET region, the first and second source/drain regions 150A and 150B may not include germanium (Ge) or may include germanium (Ge) at a lower concentration than the third and fourth source/drain regions 150C and 150D. For example, the first and second source/drain regions 150A and 150B may include silicon (Si). For example, the third and fourth source/drain regions 150C and 150D may include silicon germanium (SiGe), and a germanium (Ge) concentration of the second epitaxial layer 154 may be greater than a germanium (Ge) concentration of the first epitaxial layer 152.

A doping concentration of doping elements, i.e., impurities, in the second epitaxial layer 154 may be higher than those of the first epitaxial layer 152. Therefore, resistivity of the second epitaxial layer 154 may be lower than resistivity of the first epitaxial layer 152. For example, the impurities of the first and second source/drain regions 150A and 150B may be n-type impurities such as at least one of phosphorus (P), arsenic (As), or antimony (Sb), and the impurities of the third and fourth source/drain regions 150C and 150D may be p-type impurities such as at least one of boron (B), gallium (Ga), or indium (In). For example, an impurity concentration of the first epitaxial layer 152 may be in a range of about 1×10²⁰/cm³ to about 6×10²¹/cm³, and an impurity concentration of the second epitaxial layer 154 may be in a range of about 1×10²¹/cm³ to about 1×10²²/cm³, but the disclosure is not limited thereto.

As illustrated in FIG. 3, each of the second and fourth source/drain regions 150B and 150D may further include first and second impurity regions IR1 and IR2. The first and second impurity regions IR1 and IR2 may be disposed to contact each of the first and second backside contact plugs 180A and 180B. At least a portion of each of the first and second impurity regions IR1 and IR2 may be disposed in the first epitaxial layer 152.

The first impurity regions IR1 may be disposed along an interface between the first backside contact plug 180A and the second source/drain region 150B and an interface between the second backside contact plug 180B and the fourth source/drain region 150D. A level of an upper end of the first impurity region IR1 of the second source/drain region 150B may be higher than a level of an upper end of the first impurity region IR1 of the fourth source/drain region 150D.

The second impurity regions IR2 may be disposed on or along lower surfaces or lower portions of the second and fourth source/drain regions 150B and 150D, for example, lower surfaces of the first epitaxial layers 152. The second impurity regions IR2 may extend from the lower surfaces of the second and fourth source/drain regions 150B and 150D into the second and fourth source/drain regions 150B and 150D, and may be disposed in lower regions of the second and fourth source/drain regions 150B and 150D. In one or more embodiments, a thickness and a range of each of the first and second impurity regions IR1 and IR2 may be variously changed. The first impurity region IR1 may partially overlap the second impurity region IR2.

At least one of the first impurity regions IR1 or the second impurity regions IR2 may be regions having the highest impurity concentration in each of the second and fourth source/drain regions 150B and 150D. The first and second impurity regions IR1 and IR2 may have a higher impurity concentration than remaining regions of the second and fourth source/drain regions 150B and 150D. For example, the impurity concentration of the first and second impurity regions IR1 and IR2 may be in a range of about 2 to about 4 times the impurity concentration of the second epitaxial layer 154. For example, the impurity concentration of the first and second impurity regions IR1 and IR2 may range from about 2×10²¹/cm³ to about 4×10²²/cm³, but the disclosure is not limited thereto.

The first and second impurity regions IR1 and IR2 of the second source/drain region 150B and the first and second impurity regions IR1 and IR2 of the fourth source/drain region 150D may include different impurities. The first and second impurity regions IR1 and IR2 of the second source/drain region 150B may include the n-type impurities, e.g., at least one of phosphorus (P), arsenic (As), or antimony (Sb), or at least one of carbon (C) or argon (Ar). The first and second impurity regions IR1 and IR2 of the fourth source/drain region 150D may include the p-type impurities, e.g., at least one of boron (B), gallium (Ga), or indium (In). In each of the second and fourth source/drain regions 150B and 150D, the first impurity region IR1 may include the same or different impurity as the second impurity region IR2.

The placeholder layers 130 may be in contact with lower surfaces of the first and third source/drain regions 150A and 150C. The placeholder layers 130 may extend from the lower surfaces of the first and third source/drain regions 150A and 150C into the substrate insulating layer 110. The placeholder layers 130 may include a semiconductor material, for example, at least one of silicon (Si) or germanium (Ge), and may have a different composition from the first and third source/drain regions 150A and 150C. In one or more other embodiments, the placeholder layers 130 may additionally include impurities.

The front contact plugs 170 may penetrate the first and second interlayer insulating layers 192 and 194 to be connected to the first and third source/drain regions 150A and 150C, and may apply an electrical signal to the first and third source/drain regions 150A and 150C. The front contact plugs 170 may have an inclined side surface in which a width of a lower portion is narrower than a width of an upper portion, depending on an aspect ratio, but the disclosure is not limited thereto. The front contact plugs 170 may be disposed to recess the first and third source/drain regions 150A and 150C from the upper surfaces.

The front contact plugs 170 may recess the first and third source/drain regions 150A and 150C by substantially the same depth. The front contact plugs 170 may extend from the top, for example, below a lower surface of the uppermost first channel layer 141 of the channel structure 140, but the disclosure is not limited thereto. For example, lower ends of the front contact plugs 170 may be at a level between an upper surface of the second channel layer 142 and an upper surface of the third channel layer 143, for example. For example, the lower ends of the front contact plugs 170 may be at a level between the upper surface and the lower surface of the second channel layer 142.

The front contact plug 170 may include a first conductive layer 174 and a first metal-semiconductor compound layer 172 disposed between the first conductive layer 174 and the first and third source/drain regions 150A and 150C. The first metal-semiconductor compound layer 172 may include a metal silicide layer, such as titanium silicide (TiSi) or molybdenum silicide (MoSi), and the first conductive layer 174 may include a metal material, such as tungsten (W), molybdenum (Mo), or aluminum (Al). In one or more other embodiments, the first conductive layer 174 may include a barrier layer forming an outer surface. The barrier layer may include a metal nitride, such as titanium nitride (TiN), tantalum nitride (TaN), or tungsten nitride (WN), for example. In example embodiments, the number and arrangement of conductive layers constituting the front contact plug 170 may be variously changed.

The first and second backside contact plugs 180A and 180B may be disposed below the second and fourth source/drain regions 150B and 150D, respectively. The first and second backside contact plugs 180A and 180B may penetrate the substrate insulating layer 110 to be connected to the second and fourth source/drain regions 150B and 150D, respectively. The first backside contact plug 180A may be connected to the second source/drain region 150B in the first region R1. The second backside contact plug 180B may be connected to the fourth source/drain region 150D in the second region R2.

Each of the first and second backside contact plugs 180A and 180B may include a lower region penetrating the substrate insulating layer 110 and having a width decreasing upwardly, a middle region disposed on the lower region and having a shape corresponding or similar to the placeholder layer 130, and an upper region disposed on the middle region and recessing the second and fourth source/drain regions 150B and 150D. The upper region may have a reduced width, as compared to the middle region, and may have a width decreasing upwardly in the Z direction.

The first and second backside contact plugs 180A and 180B may be disposed to partially recess the second and fourth source/drain regions 150B and 150D from lower surfaces thereof, to contact recessed surfaces of the second and fourth source/drain regions 150B and 150D, respectively. The first and second backside contact plugs 180A and 180B may be in contact with both the first and second epitaxial layers 152 and 154 of the second and fourth source/drain regions 150B and 150D, respectively. The first and second backside contact plugs 180A and 180B may be in contact with the first epitaxial layers 152 in lower regions of the second and fourth source/drain regions 150B and 150D, respectively, and may be in contact with the second epitaxial layers 154 at upper ends thereof. Levels of upper ends of the first and second backside contact plugs 180A and 180B may be higher than levels of lower ends of the second and fourth source/drain regions 150B and 150D, respectively. The levels of the upper ends of the first and second backside contact plugs 180A and 180B may be different from each other.

As illustrated in FIG. 3, the first backside contact plug 180A may extend from a lower surface of the second source/drain region 150B into the second source/drain region 150B by a first depth D1, and the second backside contact plug 180B may extend from a lower surface of the fourth source/drain region 150D into the fourth source/drain region 150D by a second depth D2, smaller than the first depth D1. The upper end of the first backside contact plug 180A may be at a level, higher than a level of the upper end of the second backside contact plug 180B. The first backside contact plug 180A may overlap at least the second and third channel layers 142 and 143 in the X direction. For example, the first backside contact plug 180A may overlap all of the first to third channel layers 141, 142, and 143 in the X direction. The second backside contact plug 180B may overlap at least the third channel layer 143 in the X direction. For example, the second backside contact plug 180B may overlap the second and third channel layers 142 and 143 in the X direction.

In the second and fourth source/drain regions 150B and 150D, if a level corresponding to the third channel layer 143 and the gate structure 160 therebelow is referred to as a first level LV1, a level corresponding to the second channel layer 142 and the gate structure 160 therebelow is referred to as a second level LV2, and a level corresponding to the first channel layer 141 and the gate structure 160 therebelow is referred to as a third level LV3, the upper end of the first backside contact plug 180A may be at the third level LV3. For example, the upper end of the first backside contact plug 180A may be at a level, the same as or higher than a level of an upper surface of the second channel layer 142. The upper end of the first backside contact plug 180A may be at any one of a level of an upper surface of the first channel layer 141, a level of an upper surface of the second channel layer 142, or a level between the upper surface of the first channel layer 141 and the upper surface of the second channel layer 142. As another example, the upper end of the first backside contact plug 180A may be at a level between the upper surface and the lower surface of the first channel layer 141, but the disclosure is not limited thereto.

The upper end of the second backside contact plug 180B may be at the second level LV2. For example, the upper end of the second backside contact plug 180B may be at a level, or higher than a level of the upper surface of the third channel layer 143, or at a level, the same as or lower than a level of the upper surface of the second channel layer 142. The upper end of the second backside contact plug 180B may be at any one of a level of an upper surface of the second channel layer 142, a level of an upper surface of the third channel layer 143, or a level between the upper surface of the second channel layer 142 and the upper surface of the third channel layer 143. As another example, the upper end of the second backside contact plug 180B may be at a level between the upper surface and the lower surface of the second channel layer 142, but the disclosure is not limited thereto.

Each of the first and second backside contact plugs 180A and 180B may include a second conductive layer 184 passing through the substrate insulating layer 110 to extend into the second and fourth source/drain regions 150B and 150D, and a second metal-semiconductor compound layer 182 disposed between the second conductive layer 184 and each of the second and fourth source/drain regions 150B and 150D. The second metal-semiconductor compound layer 182 may form an upper end of each of the first and second backside contact plugs 180A and 180B. The second metal-semiconductor compound layer 182 may be in contact with both the first and second epitaxial layers 152 and 154 of each of the second and fourth source/drain regions 150B and 150D.

The second metal-semiconductor compound layer 182 may include a metal silicide layer, such as titanium silicide (TiSi) or molybdenum silicide (MoSi), and the second conductive layer 184 may include a metal material, such as tungsten (W), molybdenum (Mo), or aluminum (Al). In one or more other embodiments, the second metal-semiconductor compound layer 182 may include a different metal material than the second conductive layer 184. In one or more other embodiments, the second conductive layer 184 may include a barrier layer forming an outer surface. The barrier layer may include, for example, a metal nitride such as titanium nitride (TiN), tantalum nitride (TaN), or tungsten nitride (WN). In one or more embodiments, the number and arrangement of conductive layers constituting the first and second backside contact plugs 180A and 180B may be variously changed.

In the semiconductor device 100, it was confirmed through simulation results that a current density in transistors of the first region R1 and the second region R2 may be optimized according to a recess depth of the first and second backside contact plugs 180A and 180B, as described above. When the first region R1 is an nFET region and the second region R2 is a pFET region, a depth by which the second backside contact plug 180B recesses the fourth source/drain region 150D may be made relatively small, thereby reducing a recess amount of the fourth source/drain region 150D that applies stress to the first to third channel layers 141, 142, and 143, to secure channel resistance or increase carrier mobility of the transistors of the second region R2. In contrast, since a material of the second source/drain region 150B does not apply stress to the first to third channel layers 141, 142, and 143, the second source/drain region 150B may be recessed relatively deeply.

Since the second and fourth source/drain regions 150B and 150D include the first and second impurity regions IR1 and IR2, contact resistance between the first and second backside contact plugs 180A and 180B and the second and fourth source/drain regions 150B and 150D, respectively, for example, the first epitaxial layer 152 including low-concentration impurities, may be minimized. In addition, impurities of the first and second impurity regions IR1 and IR2 may diffuse into the first to third channel layers 141, 142, and 143 to reduce channel resistance. Therefore, the electrical characteristics of the semiconductor device 100 may be improved.

The first interlayer insulating layer 192 may isolate or insulate the first to fourth source/drain regions 150A, 150B, 150C, and 150D. The second interlayer insulating layer 194 may be formed on the gate structures 160 and the first interlayer insulating layer 192. The third interlayer insulating layer 196 may be formed on the lower surface of the substrate insulating layer 110. The first to third interlayer insulating layers 192, 194, and 196 may include at least one of an oxide, a nitride, or an oxynitride, and may include, for example, a low-K material. According to one or more embodiments, at least one of the first to third interlayer insulating layers 192, 194, and 196 may include a plurality of insulating layers.

The upper contacts 176 may be disposed on the front contact plugs 170 to connect the front contact plugs 170 and the upper interconnection lines 178. The backside power structures 188 may be connected to the first and second backside contact plugs 180A and 180B below the substrate insulating layer 110. The backside power structures 188, together with the first and second backside contact plugs 180A and 180B, may form a BSPDN for applying power or a ground voltage, and may also be referred to as a backside power rail or a buried power rail. For example, the backside power structures 188 may be buried interconnection lines extending in one direction, for example, in the X direction, but shapes and extension directions of the backside power structures 188 are not be limited thereto. Each of the upper contacts 176, the upper interconnection lines 178, and the backside power structures 188 may include a conductive material, for example, at least one of tungsten (W), copper (Cu), aluminum (Al), cobalt (Co), ruthenium (Ru), titanium (Ti), or molybdenum (Mo).

The semiconductor device 100 may be packaged by changing the structure of FIGS. 2A and 2B upside down such that the backside power structures 188 may be disposed in an upper portion, but a packaging form of the semiconductor device 100 is not limited thereto.

In the description of embodiments below, any description overlapping the description described above with reference to FIGS. 1 to 3 may be omitted.

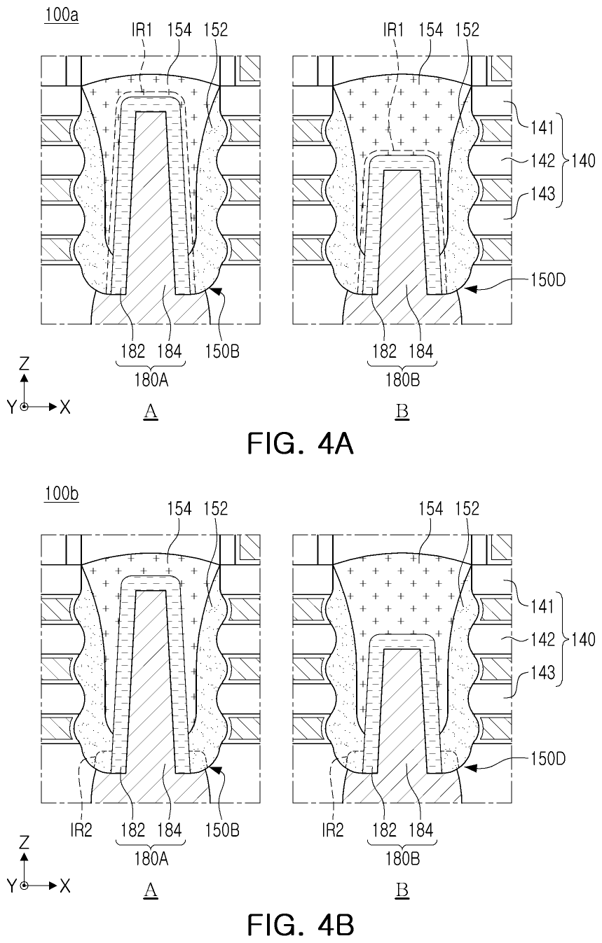

FIGS. 4A and 4B are partial enlarged views illustrating a semiconductor device, according to one or more embodiments. FIGS. 4A and 4B illustrate regions corresponding to FIG. 3.

Referring to FIG. 4A, in a semiconductor device 100a, second and fourth source/drain regions 150B and 150D may include only first impurity regions IR1, respectively. In the present embodiment, the second and fourth source/drain regions 150B and 150D may not include the second impurity region IR2 of FIG. 3. Even in this case, contact resistance between the second and fourth source/drain regions 150B and 150D and first and second backside contact plugs 180A and 180B, respectively, may be reduced by the first impurity regions IR1.

Referring to FIG. 4B, in a semiconductor device 100b, second and fourth source/drain regions 150B and 150D may include only second impurity regions IR2, respectively. In the present embodiment, the second and fourth source/drain regions 150B and 150D may not include the first impurity region IR1 of FIG. 3. Even in this case, since the second impurity regions IR2 is disposed in first epitaxial layers 152 having relatively high resistivity, contact resistance between the second and fourth source/drain regions 150B and 150D and first and second backside contact plugs 180A and 180B, respectively, may be reduced.

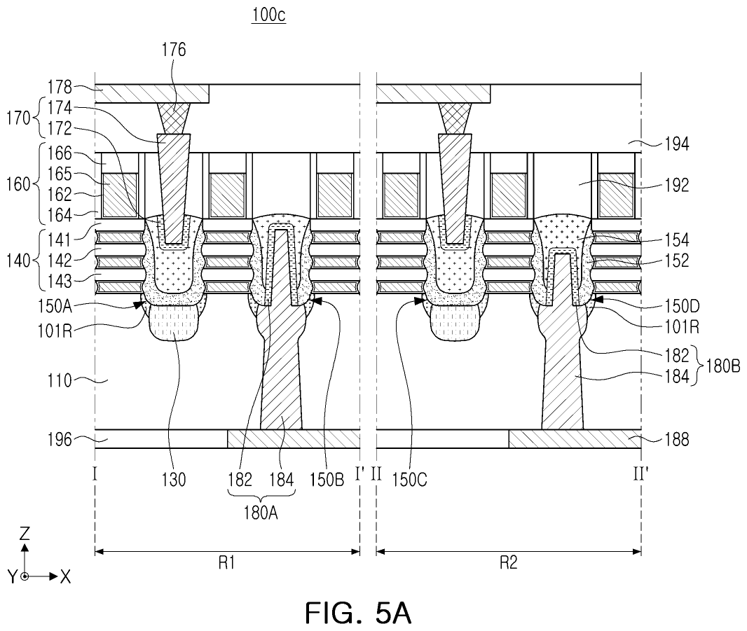

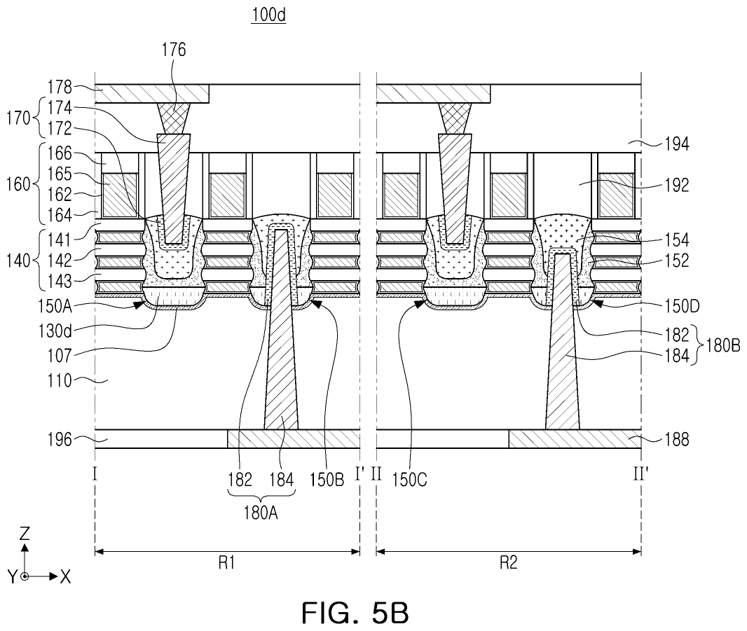

FIGS. 5A and 5B are cross-sectional views illustrating a semiconductor device, according to one or more embodiments. FIGS. 5A and 5B illustrate regions corresponding to FIG. 2A.

Referring to FIG. 5A, a semiconductor device 100c may further include remaining substrate layers 101R on a portion of each of lower surfaces of first to fourth source/drain regions 150A, 150B, 150C, and 150D.

The remaining substrate layers 101R may be disposed to have an inclined surface from the lower surfaces of the first to fourth source/drain regions 150A, 150B, 150C, and 150D or lowermost surfaces of the gate structures 160 toward side surfaces of placeholder layers 130 or side surfaces of first and second backside contact plugs 180A and 180B. The remaining substrate layers 101R may be formed on an outer side of both corner regions of each of the first to fourth source/drain regions 150A, 150B, 150C, and 150D in the X direction. The remaining substrate layers 101R may be disposed in a shape symmetrical to each other on both sides of the lower surface of each of the first to fourth source/drain regions 150A, 150B, 150C, and 150D, and may have a triangular or similar shape. In one or more embodiments, a specific shape and size of the remaining substrate layers 101R may be variously changed.

The remaining substrate layers 101R may be layers remaining without being removed when a substrate 101 (see FIG. 9A) is removed. The remaining substrate layers 101R may include a semiconductor material, for example, a group IV semiconductor, a group III-V compound semiconductor, or a group II-VI compound semiconductor. For example, the group IV semiconductor may include silicon, germanium, or silicon-germanium.

Referring to FIG. 5B, in a semiconductor device 100d, shapes and arrangement of placeholder layers 130d and shapes of first and second backside contact plugs 180A and 180B may be different from those in the embodiment of FIG. 2A. The semiconductor device 100d may further include liner layers 107.

The placeholder layers 130d may be disposed relatively higher than those in the embodiment of FIG. 2A such that upper surfaces thereof are located between portions of gate structures 160 below third channel layers 143, and may be disposed with a relatively small thickness. The placeholder layers 130d may have a thickness of, for example, about 10 nm to about 20 nm. In the present embodiment, the placeholder layers 130d may also remain below the second and fourth source/drain regions 150B and 150D. The placeholder layers 130d may function as source/drain regions, together with the first to fourth source/drain regions 150A, 150B, 150C, and 150D, but the disclosure is not limited thereto. The placeholder layers 130d may include, for example, at least one of SiGe, SiC, or SiN, and when SiGe is included, may further include at least one impurity of boron (B) or carbon (C).

The liner layers 107 may extend horizontally along lowermost surfaces of the gate structures 160 and lower surfaces of the placeholder layers 130d. The liner layers 107 may function as etch stop layers during a process of manufacturing the semiconductor device 100d, and may include, for example, a nitride.

The first and second backside contact plugs 180A and 180B may pass through the liner layer 107 and the placeholder layers 130d to extend into second and fourth source/drain regions 150B and 150D, respectively. First and second impurity regions IR1 and IR2 of the second and fourth source/drain regions 150B and 150D, as described above with reference to FIG. 3, may extend into the placeholder layers 130d in the present embodiment.

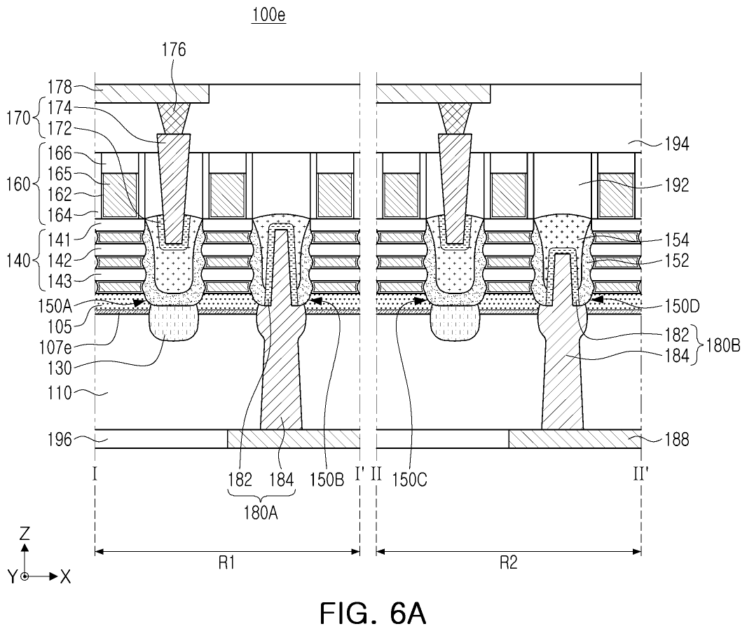

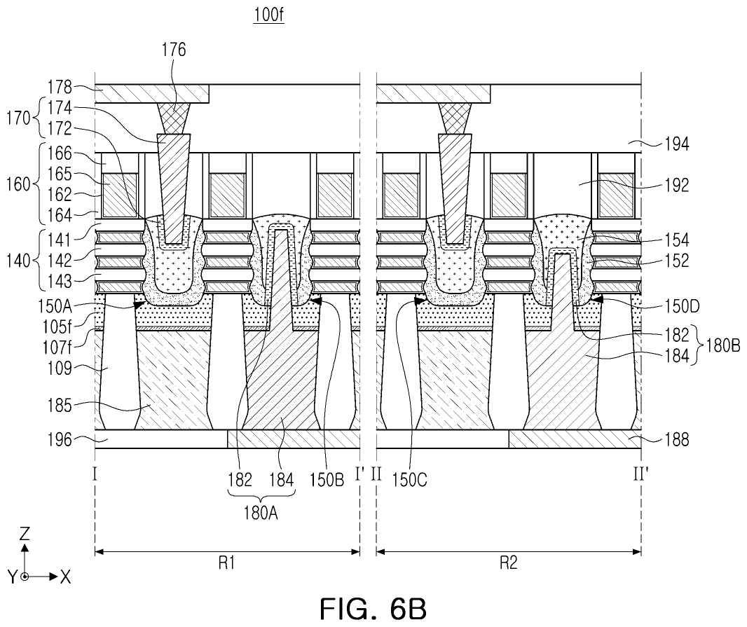

FIGS. 6A and 6B are cross-sectional views illustrating a semiconductor device, according to one or more embodiments. FIGS. 6A and 6B illustrate regions corresponding to FIG. 2A.

Referring to FIG. 6A, a semiconductor device 100e may further include active regions 105 on lowermost surfaces of gate structures 160 and lower surfaces of first to fourth source/drain regions 150A, 150B, 150C, and 150D, and liner layers 107e on lower surfaces of the active regions 105.

The active regions 105 may have a linear shape extending in the X direction, and may have substantially the same width as first to third channel layers 141, 142, and 143 in the Y direction. The active regions 105 may be separated from each other by a separate device isolation layer in the Y direction. The lower surfaces of the active regions 105 may be at a higher level than lower surfaces of placeholder layers 130.

The active regions 105 may be regions remaining without being removed when a substrate 101 (see FIG. 9A) is removed, and may be regions including impurities. The active regions 105 may include a semiconductor material, such as a group IV semiconductor, a group III-V compound semiconductor, or a group II-VI compound semiconductor. For example, the group IV semiconductor may include silicon, germanium, or silicon-germanium. The active regions 105 may include p-type impurities in a first region R1 and n-type impurities in a second region R2. In one or more other embodiments, the active regions 105 may not include impurities. First and second backside contact plugs 180A and 180B may penetrate the active regions 105 to be connected to the second and fourth source/drain regions 150B and 150D.

The liner layers 107e may extend horizontally along the lower surfaces of the active regions 105. Placeholder layers 130 and the first and second backside contact plugs 180A and 180B may be disposed to penetrate the liner layers 107e. The liner layers 107e may function as etch stop layers during a process of manufacturing the semiconductor device 100e, and may include, for example, silicon germanium (SiGe).

Referring to FIG. 6B, a semiconductor device 100f may further include active regions 105f, liner layers 107f, isolation structures 109, and dummy contact plugs 185, and may not include the substrate insulating layer 110 and the placeholder layers 130 of FIG. 2A. Shapes of first and second backside contact plugs 180A and 180B in the semiconductor device 100f may be different from those in the embodiment of FIG. 2A.

In the present embodiment, the liner layers 107f may include an insulating material. For example, the liner layers 107f may include an oxide and/or a nitride. In addition, descriptions of the active regions 105f and the liner layers 107f may be equally applied to the descriptions of the active regions 105 and the liner layers 107e described above with reference to FIG. 6A.

The isolation structures 109 may be disposed on lowermost surfaces of gate structures 160. The isolation structures 109 may penetrate the liner layers 107f and the active regions 105f to be connected to the gate structures 160, and may separate the first and second backside contact plugs 180A and 180B from the dummy contact plugs 185. The isolation structures 109 may have a shape in which a width increases and then decreases again toward a third interlayer insulating layer 196, but shapes of the isolation structures 109 are not limited thereto.

The dummy contact plugs 185 may be disposed below the liner layers 107f, and may be spaced apart from the first and second backside contact plugs 180A and 180B by the isolation structures 109. The dummy contact plugs 185 may be formed together with the first and second backside contact plugs 180A and 180B, and may include the same material as the first and second backside contact plugs 180A and 180B. The dummy contact plugs 185 may be in contact with and surrounded by the liner layers 107f, the isolation structures 109, and the third interlayer insulating layer 196. Therefore, the dummy contact plugs 185 may be dummy structures that do not perform an electrical function in the semiconductor element 100f. In one or more other embodiments, the dummy contact plugs 185 may not be formed, and an insulating layer may be disposed instead of the dummy contact plugs 185.

The first and second backside contact plugs 180A and 180B may expand horizontally below the liner layers 107f, and may fill a space between the isolation structures 109 adjacent to each other below second and fourth source/drain regions 150B and 150D, respectively. In one or more other embodiments, the first and second backside contact plugs 180A and 180B may have a structure surrounded by an insulating layer, instead of a structure expanding below the liner layers 107f.

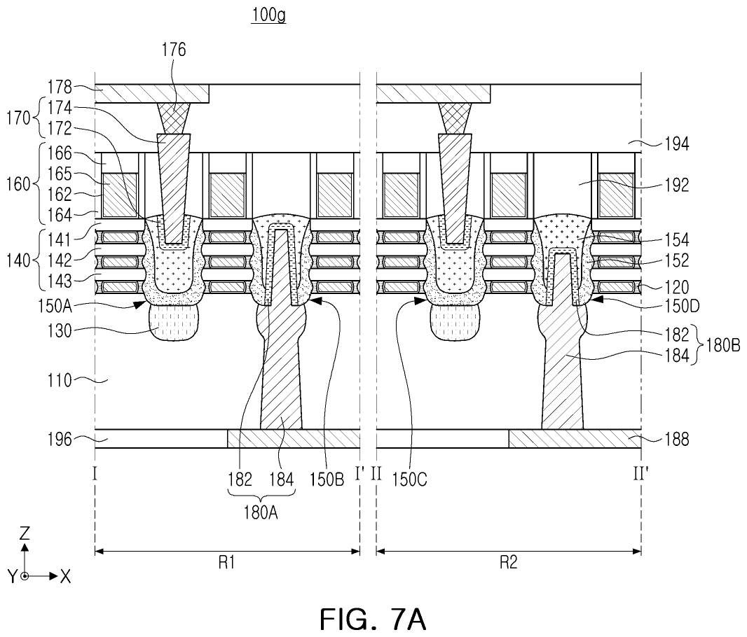

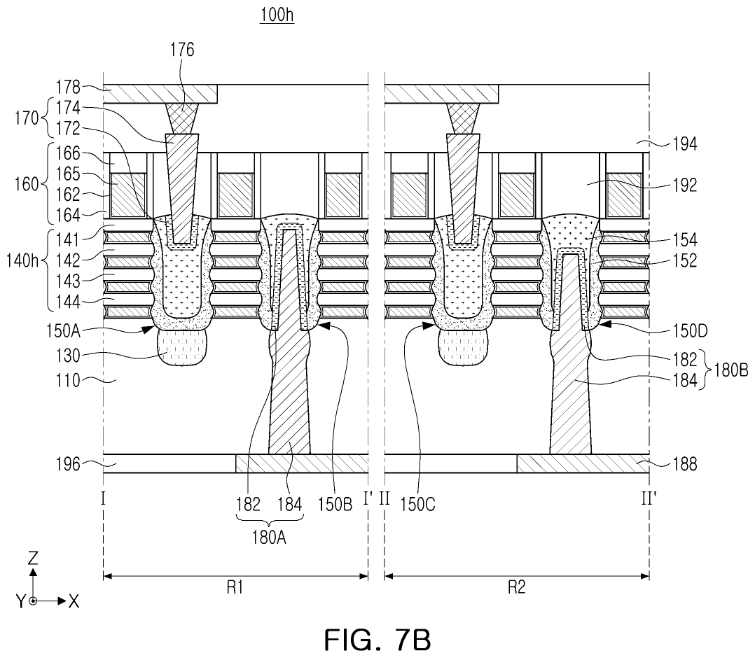

FIGS. 7A and 7B are cross-sectional views illustrating a semiconductor device, according to one or more embodiments. FIGS. 7A and 7B illustrate regions corresponding to FIG. 2A.

Referring to FIG. 7A, a semiconductor device 100g may further include internal spacer layers 120 arranged between gate dielectric layers 162 and each of first to fourth source/drain regions 150A, 150B, 150C, and 150D.

The internal spacer layers 120 may be disposed in parallel with gate structures 160, between the first to third channel layers 141, 142, and 143 in the Z direction and below the third channel layers 143. Gate electrodes 165 may be electrically isolated from the first to fourth source/drain regions 150A, 150B, 150C, and 150D by the internal spacer layers 120, and may be more stably spaced apart from each other. The internal spacer layers 120 may have a shape in which side surfaces contacting the gate structures 160 are rounded convexly outwardly toward the first to fourth source/drain regions 150A, 150B, 150C, and 150D, but the disclosure is not limited thereto. In one or more other embodiments, the internal spacer layers 120 may have a shape in which side surfaces contacting the gate structures 160 are rounded convexly inwardly toward the gate structures 160. The internal spacer layers 120 may include at least one of an oxide, a nitride, or an oxynitride, and may be formed as, for example, a low-K film. In one or more other embodiments, the internal spacer layers 120 may be disposed only in a second region R2.

Referring to FIG. 7B, in a semiconductor device 100h, channel structures 140h may include first to fourth channel layers 141, 142, 143, and 144 arranged sequentially from upper portions of the channel structures 140h. As compared to the embodiment of FIG. 2A, the channel structures 140h may further include the fourth channel layer 144. In this case, second and fourth source/drain regions 150B and 150D may have a greater thickness by a thickness of the fourth channel layer 144 and a thickness of a gate structure 160 therebelow, and first and second backside contact plugs 180A and 180B may further recess the second and fourth source/drain regions 150B and 150D by the thickness of the fourth channel layer 144 and the thickness of the gate structure 160 therebelow. With regard to levels of upper ends of the first and second backside contact plugs 180A and 180B, the description given above with reference to FIGS. 2A and 3 may be equally applied. For example, a relationship between the upper ends of the first and second backside contact plugs 180A and 180B and levels of the first to third channel layers 141, 142, and 143 may be the same as in the embodiment of FIG. 2A.

In this manner, in one or more embodiments, even when the number of channel layers forming a channel structure is changed to be four or more, positions of the upper ends of the first and second backside contact plugs 180A and 180B may be determined, based on three uppermost channel layers 141, 142, and 143.

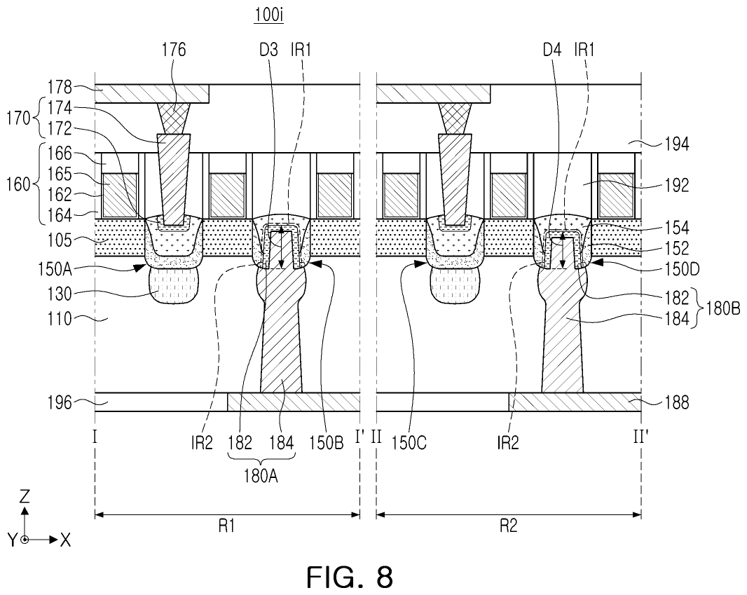

FIG. 8 is a cross-sectional view illustrating a semiconductor device, according to one or more embodiments. FIG. 8 illustrates a region corresponding to FIG. 2A.

Referring to FIG. 8, a semiconductor device 100i may include active regions 105 as channel structures, different from the channel structures 140 shown in FIGS. 1 to 2B, and accordingly, arrangement of gate structures 160 may be different from the embodiments of FIGS. 1 to 2B. Transistors formed of the active regions 105 in the semiconductor device 100i may each be a FinFET structure not including a separate channel layer.

In the semiconductor device 100i, physical channel regions of the transistors are limited to the active regions 105 of a fin structure. Separate channel layers are not interposed in the gate structures 160. In one or more other embodiments, liner layers 107e may be further arranged on lower surfaces of the active regions 105, similarly to the embodiment of FIG. 6A.

First and second backside contact plugs 180A and 180B may recess second and fourth source/drain regions 150B and 150D by depths different from each other. The first backside contact plug 180A may recess the second source/drain region 150B by a third depth D3 from a lower surface of the second source/drain region 150B, and the second backside contact plug 180B may recess the fourth source/drain region 150D by a fourth depth D4, smaller than the third depth D3, from a lower surface of the fourth source/drain region 150D. For example, when the second source/drain region 150B is divided into an upper region, a middle region, and a lower region, an upper end of the first backside contact plug 180A may be in the upper region. For example, when the fourth source/drain region 150D is divided into an upper region, a middle region, and a lower region, an upper end of the second backside contact plug 180B may be in the middle region.

The second and fourth source/drain regions 150B and 150D may include first and second impurity regions IR1 and IR2, respectively, and the description given above with reference to the embodiments of FIGS. 1 to 2B may be equally applied.

Such a semiconductor device 100i may also be additionally arranged in one region of the semiconductor device of other embodiments.

FIGS. 9A to 9N are views illustrating a process sequence illustrating a method of manufacturing a semiconductor device, according to one or more embodiments. FIGS. 9A to 9N illustrate an embodiment of a manufacturing method for manufacturing a power semiconductor device of FIGS. 1 to 2B. FIGS. 9A to 9N illustrate cross-sections taken along lines I-I′ and II-II′ of FIG. 1, respectively.

Referring to FIG. 9A, sacrificial layers 118 and first to third channel layers 141, 142, and 143 may be alternately stacked on a substrate 101.

The substrate 101 may include silicon (Si), germanium (Ge), or silicon germanium (SiGe). The substrate 101 may include a bulk wafer, an epitaxial layer, a silicon-on-insulator (SOI) layer, or a semiconductor-on-insulator (SeOI) layer.

The sacrificial layers 118 may be layers that may be replaced with gate dielectric layers 162 and gate electrodes 165 by subsequent processes, as illustrated in FIGS. 2A and 2B. The sacrificial layers 118 may be formed of a material having etch selectivity with respect to the first to third channel layers 141, 142, and 143, respectively. The first to third channel layers 141, 142, and 143 may include a material different from the sacrificial layers 118. The sacrificial layers 118 and the first to third channel layers 141, 142, and 143 may include, for example, a semiconductor material including at least one of silicon (Si), silicon germanium (SiGe), or germanium (Ge), but may include different materials, and may or may not include impurities. For example, the sacrificial layers 118 may include silicon germanium (SiGe), and the first to third channel layers 141, 142, and 143 may include silicon (Si) without germanium (SiGe) or with a very low germanium (Ge) concentration.

The sacrificial layers 118 and the first to third channel layers 141, 142, and 143 may be formed by performing an epitaxial growth process from the substrate 101. The number of layers of the channel layers 141, 142, and 143 alternately stacked with the sacrificial layers 118 may be more or less than three, according to one or more other embodiments.

Referring to FIG. 9B, a portion of the sacrificial layers 118, a portion of the first to third channel layers 141, 142, and 143, and a portion of the substrate 101 may be removed to form active structures, and sacrificial gate structures 200 and gate spacer layers 164 may be formed on the active structures.

The active structures may include the sacrificial layers 118 and the first to third channel layers 141, 142, and 143, alternately stacked, and may further include active regions 105 that may be formed by removing the portion of the substrate 101 to protrude from the substrate 101. The active structures may be formed in a linear shape extending in one direction, for example, in the X direction, and may be formed to be spaced apart from each other in the Y direction. The active regions 105 may include different impurities in first and second regions R1 and R2. In one or more other embodiments, the active regions 105 may not include impurities. A device isolation layer may be formed between adjacent active regions 105 in the Y direction.

The sacrificial gate structures 200 may be sacrificial structures formed in regions in which the gate dielectric layers 162 and the gate electrodes 165 are disposed on channel structures 140 by a subsequent process, as illustrated in FIGS. 2A and 2B. The sacrificial gate structures 200 may have a linear shape extending in one direction while intersecting the active structures. The sacrificial gate structures 200 may extend in the Y direction, for example.

Each of the sacrificial gate structures 200 may include first and second sacrificial gate layers 202 and 205 and a mask pattern layer 206, sequentially stacked. The first and second sacrificial gate layers 202 and 205 may be patterned using the mask pattern layer 206. The first and second sacrificial gate layers 202 and 205 may be an insulating layer and a conductive layer, respectively, but the disclosure is not limited thereto, and the first and second sacrificial gate layers 202 and 205 may be formed as a single layer. For example, the first sacrificial gate layer 202 may include silicon oxide, and the second sacrificial gate layer 205 may include polysilicon. The mask pattern layer 206 may include silicon oxide and/or silicon nitride.

Gate spacer layers 164 may be formed on both sidewalls of the sacrificial gate structures 200. The gate spacer layers 164 may be formed of a low-K material, and may include at least one of SiO, SiN, SiCN, SiOC, SiON, or SiOCN, for example.

Referring to FIG. 9C, the sacrificial layers 118 and the first to third channel layers 141, 142, and 143, exposed by the sacrificial gate structures 200, may be partially removed to form recess regions RC.

First, the sacrificial gate structures 200 and the gate spacer layers 164 may be used as masks to remove the exposed sacrificial layers 118 and the first to third channel layers 141, 142, and 143, and the active regions 105 may be partially removed to form recess regions. As a result, the first to third channel layers 141, 142, and 143 may form the channel structures 140 having a limited length in the X direction.

Referring to FIG. 9D, the active regions 105 exposed through the recess regions RC may be further removed to form extended recess regions RC′.

The active regions 105 exposed through the recess regions RC may be further recessed by a predetermined depth, to form the extended recess regions RC′ in the Z direction. In this operation, for example, after sacrificial spacer layers SS may be formed on both sidewalls of the recess regions RC, the active regions 105 may be partially etched and removed. The sacrificial spacer layers SS may include a different material from the active regions 105, for example, silicon nitride. Therefore, in the extended recess regions RC′, lower regions extended in this operation may have a narrower width than the existing recess regions RC.

Referring to FIG. 9E, placeholder layers 130 and first to fourth source/drain regions 150A, 150B, 150C, and 150D may be formed.

The placeholder layers 130 may be grown from the active regions 105, for example, by a selective epitaxial process. The placeholder layers 130 may include a semiconductor material having a different composition from the first to fourth source/drain regions 150A, 150B, 150C, and 150D to be formed subsequently. After the formation of the placeholder layers 130, the sacrificial spacer layers SS may be removed. In one or more other embodiments, the sacrificial spacer layers SS may remain on both sides of the placeholder layers 130.

The first to fourth source/drain regions 150A, 150B, 150C, and 150D may be formed by growing from side surfaces of the channel structures 140, the active regions 105, and the placeholder layers 130, for example, by a selective epitaxial process. The first and second source/drain regions 150A and 150B and the third and fourth source/drain regions 150C and 150D may be formed by different processes, and may have different compositions. The first to fourth source/drain regions 150A, 150B, 150C, and 150D may include impurities by in-situ doping. Each of the first to fourth source/drain regions 150A, 150B, 150C, and 150D may include first and second epitaxial layers 152 and 154. The first and second epitaxial layers 152 and 154 may have different concentrations of non-silicon elements.

Referring to FIG. 9F, a first interlayer insulating layer 192 may be formed, and the sacrificial layers 118 and the sacrificial gate structure 200 may be removed.

The first interlayer insulating layer 192 may be formed by forming an insulating film on the sacrificial gate structure 200 and the first to fourth source/drain regions 150A, 150B, 150C, and 150D and performing a planarization process.

The sacrificial layers 118 and the sacrificial gate structures 200 may be selectively removed with respect to the gate spacer layers 164, the first interlayer insulating layer 192, the first to fourth source/drain regions 150A, 150B, 150C, and 150D, and the channel structures 140. First, the sacrificial gate structure 200 may be removed to form an upper gap region UR, and then the sacrificial layers 118 exposed through the upper gap region UR may be removed to form lower gap regions LR. For example, when the sacrificial layers 118 include silicon germanium (SiGe) and the channel structures 140 include silicon (Si), the sacrificial layers 118 may be selectively removed by performing a wet etching process.

Referring to FIG. 9G, the gate dielectric layers 162 and the gate electrodes 165 may be formed to form gate structures 160, and a second interlayer insulating layer 194, front contact plugs 170, upper contacts 176, and upper interconnection lines 178 may be formed.

The gate dielectric layers 162 and the gate electrodes 165 may be formed to fill the upper gap regions UR and the lower gap regions LR. The gate dielectric layers 162 may be conformally formed on internal surfaces of the upper gap regions UR and internal surfaces of the lower gap regions LR. The gate electrodes 165 may be formed to fill the upper gap regions UR and the lower gap regions LR, and may be then removed from the upper gap regions UR by a predetermined depth, together with the gate dielectric layers 162 and the gate spacer layers 164, and gate capping layers 166 may be formed.

The second interlayer insulating layer 194 may be formed on the gate structures 160. The second interlayer insulating layer 194 may be partially formed, and the front contact plugs 170 penetrating a portion of the second interlayer insulating layer 194 and the first interlayer insulating layer 192 may be formed. The upper contacts 176 and the upper interconnection lines 178 may be sequentially formed on the front contact plugs 170. When there is an additional interconnection structure arranged on the upper interconnection lines 178, the interconnection structure may be further formed in this operation.

Referring to FIG. 9H, the substrate 101 and the active regions 105 may be removed.

First, although not specifically illustrated, to perform a process on a lower surface of the substrate 101, a separate carrier substrate may be formed on the second interlayer insulating layer 194, a structure formed may be entirely turned over, and the following processes may be performed.

The substrate 101 and the active regions 105 may be partially removed and thinned by, for example, a lapping process, a grinding process, and/or a polishing process, and a remaining region may also be removed by an etching process and/or an oxidation process. In one or more other embodiments, such as the embodiments of FIGS. 5A, 6A, and 6B, the substrate 101 or the active regions 105 may not be completely removed, and may partially remain.

Referring to FIG. 9I, a substrate insulating layer 110 may be formed, through-holes exposing the placeholder layers 130 below the second and fourth source/drain regions 150B and 150D may be formed, and the placeholder layers 130 exposed through the through-holes may be removed.

The substrate insulating layer 110 may be formed in a region from which the substrate 101 and the active regions 105 are removed. The substrate insulating layer 110 may include, for example, silicon oxide.

Next, a separate mask layer may be formed on a lower surface of the substrate insulating layer 110, through-holes penetrating the substrate insulating layer 110 to expose the placeholder layers 130 below the second and fourth source/drain regions 150B and 150D, and the exposed placeholder layers 130 may be selectively removed. By this operation, first and second contact holes CTH1 and CTH2 exposing lower surfaces of the second and fourth source/drain regions 150B and 150D may be formed.

Referring to FIG. 9J, a first ion implantation process IP1 may be performed on the second source/drain region 150B to form a second impurity region IR2.

First, a first mask layer ML1 exposing the first contact hole CTH1 may be formed. The first mask layer ML1 may be, for example, a photoresist layer.

N-type impurities, for example, at least one of phosphorus (P), arsenic (As), or antimony (Sb), may be injected into the second source/drain region 150B through the first contact hole CTH1. Alternatively, instead of or in addition to the n-type impurity, at least one of carbon (C) or argon (Ar) may be implanted into the second source/drain region 150B. When carbon (C) and argon (Ar) are implanted, they may diffuse doping elements in the second source/drain region 150B into an interior of the second source/drain region 150B. As a result, the second impurity region IR2 may be formed in a lower region including the lower surface of the second source/drain region 150B.

Referring to FIG. 9K, after the first contact hole CTH1 is expanded to recess the second source/drain region 150B, a second ion implantation process IP2 may be performed on the second source/drain region 150B to form a first impurity region IR1.

The second source/drain region 150B may be etched from a lower surface by a first depth D1 to form an expanded first contact hole CTH1′, and the second ion implantation process IP2 may be performed. At least one of phosphorus (P), arsenic (As), antimony (Sb), carbon (C), or argon (Ar) may be injected into the second source/drain region 150B through the second ion implantation process IP2. As a result, the first impurity region IR1 may be formed along the recessed surface of the second source/drain region 150B.

As in the embodiments of FIGS. 4A and 4B, in one or more other embodiments, only one of the first ion implantation process IP1 or the second ion implantation process IP2 may be performed.

Referring to FIG. 9L, a third ion implantation process IP3 may be performed on the fourth source/drain region 150D to form a second impurity region IR2.

First, a second mask layer ML2 exposing the second contact hole CTH2 may be formed. The second mask layer ML2 may be, for example, a photoresist layer.

P-type impurities, for example, at least one of boron (B), gallium (Ga), or indium (In), may be injected into the fourth source/drain region 150D through the second contact hole CTH2. As a result, the second impurity region IR2 may be formed in a lower region including the lower surface of the fourth source/drain region 150D.

Referring to FIG. 9M, after the second contact hole CTH2 is expanded to recess the fourth source/drain region 150D, a fourth ion implantation process IP4 may be performed on the fourth source/drain region 150D to form a first impurity region IR1.

The fourth source/drain region 150D may be etched from a lower surface by a second depth D2, smaller than the first depth D1, to form an expanded second contact hole CTH2′, and the fourth ion implantation process IP4 may be performed. At least one of boron (B), gallium (Ga), or indium (In) may be injected into the fourth source/drain region 150D through the fourth ion implantation process IP4. As a result, the first impurity region IR1 may be formed along the recessed surface of the fourth source/drain region 150D.

As in the embodiments of FIGS. 4A and 4B, in one or more other embodiments, only one of the third ion implantation process IP3 and the fourth ion implantation process IP4 may be performed.

In one or more other embodiments, processes for the second region R2 described above with reference to FIGS. 9L and 9M may be performed first, and processes for the first region R1 described above with reference to FIGS. 9J and 9K may be then performed.

Referring to FIG. 9N, first and second backside contact plugs 180A and 180B may be formed.

An operation of forming the first and second backside contact plugs 180A and 180B may include an operation of forming second metal-semiconductor compound layers 182 along the recessed surfaces of the second and fourth source/drain regions 150B and 150D within the extended first and second contact holes CTH1′ and CTH2′, and an operation of forming second conductive layers 184 filling the first and second contact holes CTH1′ and CTH2′.

Next, referring back to FIG. 2A, a third interlayer insulating layer 196 may be formed and partially removed, to form backside power structures 188 connected to the first and second backside contact plugs 180A and 180B. As a result, the semiconductor device 100 of FIGS. 1 to 2B may be manufactured.

According to one or more embodiments, a backside contact plug forming process may be optimized, depending on characteristics of a transistor, to provide a semiconductor device having improved electrical characteristics

Various advantages and effects of the disclosure are not limited to the above-described contents, and can be more easily understood in the process of describing specific embodiments.

While example embodiments have been illustrated and described above, it will be apparent to those skilled in the art that modifications and variations could be made without departing from the scope of the disclosure as defined by the appended claims.

What is claimed is:

1. A semiconductor device comprising:
a first source/drain region and a second source/drain region on a first channel structure;
a third source/drain region and a fourth source/drain region on a second channel structure;
a first backside contact plug recessing the second source/drain region by a first depth from a lower surface of the second source/drain region; and
a second backside contact plug recessing the fourth source/drain region by a second depth, smaller than the first depth, from a lower surface of the fourth source/drain region,
wherein the second source/drain region comprises a first impurity region comprising a first impurity on an interface with the first backside contact plug, and
wherein the fourth source/drain region comprises another first impurity region comprising a second impurity on an interface with the second backside contact plug.

2. The semiconductor device of claim 1, wherein the second source/drain region comprises:
a first epitaxial layer on side surfaces of the first channel structure and having a first impurity concentration; and
a second epitaxial layer on the first epitaxial layer and having a second impurity concentration, higher than the first impurity concentration,
wherein an impurity concentration in the first impurity region is higher than the second impurity concentration of the second epitaxial layer.

3. The semiconductor device of claim 2, wherein the second source/drain region further comprises a second impurity region on a lower portion of the first epitaxial layer and comprising an impurity, the same as or different from the first impurity.

4. The semiconductor device of claim 3, wherein at least one of the first impurity region or the second impurity region has the highest impurity concentration in the second source/drain region.

5. The semiconductor device of claim 1, wherein the first impurity comprise at least one of phosphorus (P), arsenic (As), antimony (Sb), carbon (C), and argon (Ar).

6. The semiconductor device of claim 1, wherein the second impurity comprise at least one of boron (B), gallium (Ga), or aluminum (Al).

7. The semiconductor device of claim 1, wherein each of the first and second channel structures comprise a first channel layer, a second channel layer, and a third channel layer, which are sequentially arranged from an upper portion thereof, and
wherein an upper end of the first backside contact plug is on a level, the same as or higher than a level of an upper surface of the second channel layer.

8. The semiconductor device of claim 7, wherein an upper end of the second backside contact plug is between a level of an upper surface of the third channel layer, and a level of the upper surface of the second channel layer.

9. The semiconductor device of claim 1, wherein each of the first and second backside contact plugs comprises:
a conductive layer extended into each of the second and fourth source/drain regions; and
a metal-semiconductor compound layer between the conductive layer and each of the second and fourth source/drain regions, and the metal-semiconductor compound layer forming an upper end of each of the first and second backside contact plugs.

10. The semiconductor device of claim 9, wherein each of the second and fourth source/drain regions comprises a first epitaxial layer on side surfaces of the channel structure, and a second epitaxial layer on the first epitaxial layer, and
wherein the metal-semiconductor compound layer is in contact with both the first and second epitaxial layers.

11. The semiconductor device of claim 1, wherein the first region is an n-type field-effect transistor (nFET) region and the second region is a p-type field-effect transistor (pFET) region.

12. The semiconductor device of claim 1, further comprising:
a first front contact plug recessing the first source/drain region from an upper surface of the first source/drain region; and
a second front contact plug recessing the third source/drain region from an upper surface of the third source/drain region.

13. The semiconductor device of claim 12, wherein a depth by which the first front contact plug recesses the first source/drain region is substantially equal to a depth by which the second front contact plug recesses the third source/drain region.

14. The semiconductor device of claim 1, further comprising a placeholder layer below a lower surface of the first source/drain region or the third source/drain region.

15. A semiconductor device comprising:
a first source/drain region and a second source/drain region spaced apart from each other; and
a first backside contact plug and a second backside contact plug on the first source/drain region and the second source/drain region, respectively,
wherein the first source/drain region comprises a first impurity region along an interface with the first backside contact plug, and a second impurity region along a lower portion of the first source/drain region,
wherein the second source/drain region comprises a third impurity region along an interface with the second backside contact plug, and a fourth impurity region along a lower portion of the second source/drain region, and
wherein the first impurity region comprises an impurity different from an impurity in the third impurity region, and the second impurity region comprises an impurity different from an impurity in the fourth impurity region.

16. The semiconductor device of claim 15, wherein an upper end of the first impurity region is at a level higher than a level of an upper end of the third impurity region.

17. The semiconductor device of claim 15, further comprising:
a first channel structure on the first source/drain region; and
a second channel structure on the second source/drain region,
wherein each of the first and second source/drain regions comprises a first epitaxial layer on each of the first and second channel structures, and a second epitaxial layer on the first epitaxial layer, and
wherein, at least a portion of each of the first to fourth impurity regions is in the first epitaxial layer.

18. The semiconductor device of claim 15, wherein the first and second impurity regions comprise at least one of an n-type impurity, carbon (C), or argon (Ar), and
wherein the third and fourth impurity regions comprise a p-type impurity.

19. A semiconductor device comprising:
a first source/drain region and a second source/drain region spaced apart from each other;
a first backside contact plug recessing the first source/drain region by a first depth from a lower surface of the first source/drain region; and
a second backside contact plug recessing the second source/drain region from a lower surface of the second source/drain region by a second depth, different from the first depth,
wherein the first source/drain region comprises a first impurity region comprising a first impurity in a region contacting the first backside contact plug, and
wherein the second source/drain region comprises a second impurity region comprising a second impurity in a region contacting the second backside contact plug.

20. The semiconductor device of claim 19, wherein the second source/drain region comprises a p-type impurity,
wherein the second impurity is of p-type, and
wherein impurity concentration in the second impurity region in the second source/drain region is higher than other regions in the second source/drain region.
